(19) United States
(12) Patent Application Publication
(10) Pub. No.: US 2010/0308400 A1
(43) Pub. Date: Dec. 9, 2010

(54) Semiconductor Power Switches Having Trench Gates

(75) Inventors: Mohamed N. Darwish, Campbell, CA (US); Jun Zeng, Torrence, CA (US)

Correspondence Address: GROOVER & Associates, BOX 802889, DALLAS, TX, 75380-2889, US

(73) Assignee: MaxPower Semiconductor Inc., Campbell, CA (US)

(21) Appl. No.: 12/431,852

(22) Filed: Apr. 29, 2009

Related U.S. Application Data
(60) Provisional application No. 61/074,162, filed on Jun. 20, 2008.
(60) Provisional application No. 61/076,767, filed on Jun. 30, 2008.

(51) Int. Cl. H01L 29/78; H01L 21/28

(52) U.S. Cl. 257/330; 438/589; 257/E21.19; 257/E29.262

(57) ABSTRACT

A method of fabricating a trench device includes forming a first trench and forming a hardmask layer on sidewalls of the trench. A second trench may be etched narrower than the first trench, into the bottom of the first trench. A dielectric material may be grown to substantially fill the second trench, using a reaction process to which the hardmask material is substantially inert. The growing action also grows tapered portions of the dielectric material upwardly under part of the hardmask. A conductive layer may be formed over said dielectric material. The dielectric material in the second trench, in combination with the tapered portions which extend upward from the dielectric material may provide smooth gradation of voltage differences within the semiconductor material. The gradation may be caused by potential differences between the gate and various portions of the semiconductor material.

### CROSS-REFERENCE TO OTHER APPLICATION

Priority is claimed from provisional application Ser. Nos. 61/074,162, filed Jun. 20, 2008, and 61/076,767, filed Jun. 30, 2008, which are hereby incorporated by reference.

### BACKGROUND

The present application relates to semiconductor switches, and more particularly to power MOSFET semiconductor switches including gate trenches.

Note that the points discussed below may reflect the hindsight gained from the disclosed inventions, and are not necessarily admitted to be prior art.

### BRIEF DESCRIPTION OF THE DRAWINGS

The disclosed inventions will be described with reference to the accompanying drawings, which show important sample embodiments of the invention and which are incorporated in the specification hereof by reference, wherein:

FIG. 1 is a cross-sectional view depicting a trench MOSFET in accordance with the prior art;

FIG. 2(a) is a cross-sectional view depicting a trench MOSFET having a thick bottom oxide, in accordance with the prior art;

FIG. 2(b) is a cross-sectional view depicting a trench MOSFET having a stepped gate oxide, in accordance with the prior art;

FIG. 2(c) is a cross-sectional view depicting a trench MOSFET having deposited oxide, in accordance with the prior art;

FIG. 3 is a cross-sectional view depicting a trench MOSFET having a high-aspect ratio bottom gate oxide and a smooth gate oxide transition region, in accordance with an embodiment;

FIG. 4 is a cross-sectional view depicting a trench MOSFET having a high-aspect ratio bottom gate oxide and a smooth gate oxide transition region, in accordance with an embodiment;

FIGS. 5(a) and (b) are cross-sectional views depicting trench MOSFETs having a high aspect ratio bottom gate oxide, a smooth oxide transition region and recessed field plates, in accordance with sample embodiments;

FIGS. 6(a)-6(m) are cross-sectional views depicting stages in forming a trench MOSFET, in accordance with an embodiment;

FIG. 7 is a cross-sectional view depicting a conventional trench MOSFET in accordance with the prior art;

FIG. 8 is a cross-sectional structural diagram depicting a trench UMOS including a split polysilicon gate in accordance with the prior art;

FIG. 9 is a cross-sectional structural diagram depicting a trench UMOS including a recessed field plate in accordance with the prior art;

FIG. 10 is a cross-sectional structural diagram depicting a trench UMOS including a recessed field plate, in accordance with an embodiment;

FIG. 11 is a series of cross-sectional structural diagrams depicting trench fills;

FIG. 12 is a graph plotting sheet resistance by polysilicon height;

FIG. 13 is a cross-sectional structural diagram depicting a process stage, in accordance with an embodiment;

FIG. 14 is a cross-sectional structural diagram depicting a process stage, in accordance with an embodiment;

FIG. 15 is a cross-sectional structural diagram depicting a process stage, in accordance with an embodiment;

FIG. 16 is a cross-sectional structural diagram depicting a process stage, in accordance with an embodiment;

FIG. 17 is a cross-sectional structural diagram depicting a process stage, in accordance with an embodiment;

FIG. 18 is a cross-sectional structural diagram depicting a process stage, in accordance with an embodiment;

FIG. 19 is a cross-sectional structural diagram depicting a process stage, in accordance with an embodiment;

FIG. 20 is a cross-sectional structural diagram depicting a process stage, in accordance with an embodiment;

FIG. 21 is a cross-sectional structural diagram depicting a process stage, in accordance with an embodiment;

FIG. 22 is a cross-sectional structural diagram depicting a process stage, in accordance with an embodiment;

FIG. 23 is a cross-sectional structural diagram depicting a process stage, in accordance with an embodiment;

FIG. 24 is a cross-sectional structural diagram depicting a UMOS without a recessed field plate, in accordance with an embodiment;

FIG. 25 is a cross-sectional structural diagram depicting a process stage, in accordance with an embodiment;

FIG. 26 is a cross-sectional structural diagram depicting a process stage, in accordance with an embodiment;

FIG. 27 is a cross-sectional structural diagram depicting a process stage, in accordance with an embodiment;

FIG. 28 is a cross-sectional structural diagram depicting a process stage, in accordance with an embodiment;

FIG. 29 is a cross-sectional structural diagram depicting a process stage, in accordance with an embodiment;

FIG. 30 is a cross-sectional structural diagram depicting a process stage, in accordance with an embodiment;

FIG. 31 is a cross-sectional structural diagram depicting a process stage, in accordance with an embodiment;

FIG. 32 is a cross-sectional structural diagram depicting a process stage, in accordance with an embodiment; and

FIG. 33 is a cross-sectional structural diagram depicting a UMOS including a recessed field plate, in accordance with an embodiment.

### DETAILED DESCRIPTION OF SAMPLE EMBODIMENTS

Power MOSFETs are widely used as switching devices in many electronic applications. In order to minimize conduction power loss it is desirable that power MOSFETs have low specific on-resistance (Rₛₚ). Rₛₚ is defined as the product of the device's on-resistance (Rₒₙ) and the active die area (A), such that Rₛₚ=Rₒₙ*A.

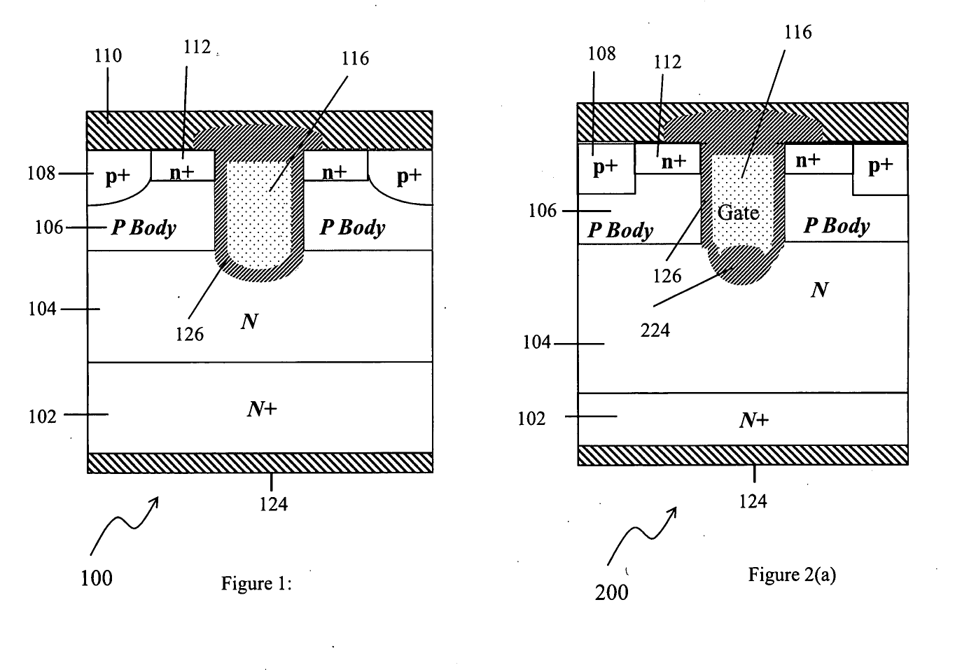

With reference to FIG. 1, a cross-sectional structural diagram depicts a typical trench MOSFET 100. A backside drain contact 124 contacts a heavily-doped deep drain region 102 (doped n+ in this example). A shallow drain region (or “drift region”) 104 adjoins the heavily-doped drain region 102. The shallow drain region 104 may be, for example, doped n-type, for an N-channel device. A body region 106 may be doped p-type. The body region 106 may be formed between the drain region 104 and the source region 112. A p+ body contact region 108 makes contact to the body region 106. An insulation trench region 126 may typically be formed with silicon dioxide or any other suitable dielectric or insulation material. The insulation trench region 126 may extend above the silicon surface of the source 112. A gate electrode 116, typically formed of polysilicon or polycide, is positioned within a trench which has sidewall insulation 126. Source and body metallization 110 connects to the source 112 and the body contact region 108. The gate 116 is capacitively coupled, through insulator 126, to controllably invert part of body 106 (when the gate voltage is high enough) to thereby allow electron flow from source to drain.

Such a trench MOSFET 100 provides a lower specific on-resistance Rₛₚ as the cell pitch decreases due to high packing density or number of cells per unit area. However, as the cell density increases, the associated capacitances, such as the gate-drain capacitance (C_{gd}), the total input capacitance (Cᵢₛₛ), the total output capacitance (Cₒₛₛ), and the gate-source capacitance (C_{gs}), also increase. As a consequence of these increased capacitances, there is an increase in the switching power losses of the device. In many switching applications, such as synchronous buck DC-DC converters used in mobile products, MOSFETs may be required to operate at high switching frequencies, approaching the megahertz range, requiring low switching losses.

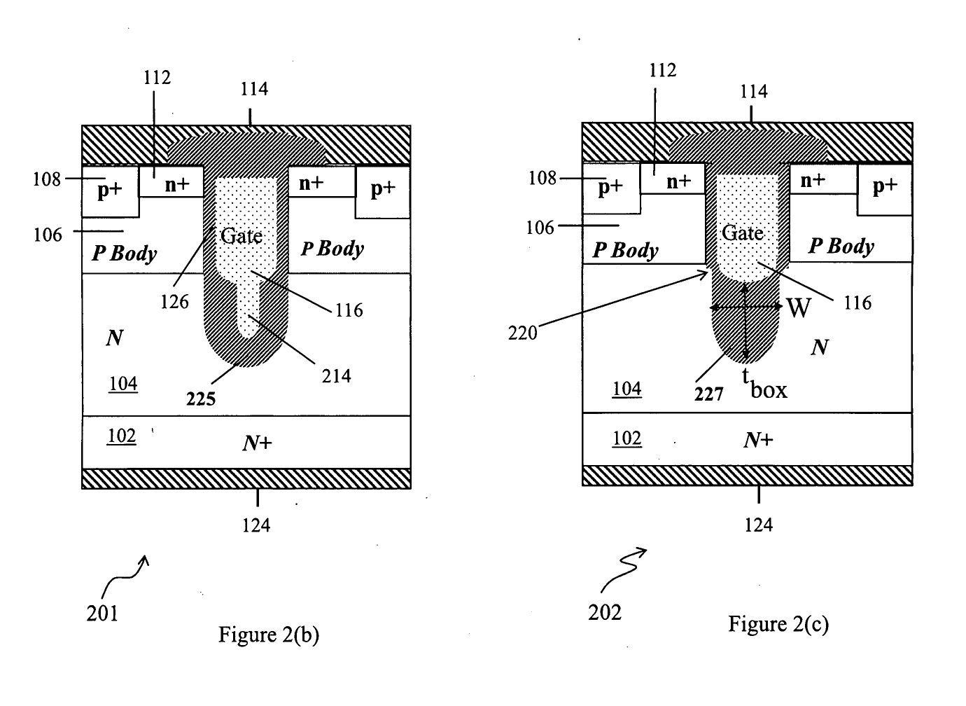

A structure with lower gate-drain capacitances C_{gd} or gate-drain charge Q_{gd} may minimize switching losses. One approach to reducing these capacitances is shown in FIG. 2(a), which shows a modification of the structure of FIG. 1. In this example a thickened oxide 224 lies below the gate electrode 116. Other elements are generally similar, and are therefore shown with the same reference numbers as in FIG. 2(a).

Another alternative is shown in FIG. 2(b). In this case the gate oxide 126 in the channel region is supplemented by a much thicker oxide 225 on the bottom portion of the trench. The gate electrode 116 has a downward extension 214 which improves on-resistance and gate sheet resistance, while minimizing the increase in C_{gd}.

As devices are scaled to achieve high cell density (and better current density per unit of wafer area), the trench width becomes narrower. With such scaling the structures shown in FIGS. 2(a) and (b) become unsuitable, i.e. they cannot achieve the high aspect ratio of bottom oxide thickness (t_{Box}) to trench width (W) (t_{Box}/W), e.g. greater than 1.0 and preferably between 1 to 4 which is required for low C_{gd}.

The structure shown in FIG. 2(c) can achieve a high aspect ratio (t_{Box}/W) by using deposited oxide 227 (such as LTO, TEOS or High Density Plasma HDP) and etch back techniques. However, using this approach results in a structure with thin oxide or “dent” areas 220 at the transition region between the grown trench wall oxide and the thick bottom oxide. This oxide may be thinner than that of the trench wall at the channel, and will be subject to higher electric field (since the “dent” locations 220 will be adjacent to the shallow drain 104). This may result in compromising the device reliability and can result in lower breakdown voltage. Other elements in this drawing are generally similar to those in one or more preceding drawings, and are therefore shown with the same reference numbers. Furthermore, in narrow trenches the above method results in voids in the oxide layer.

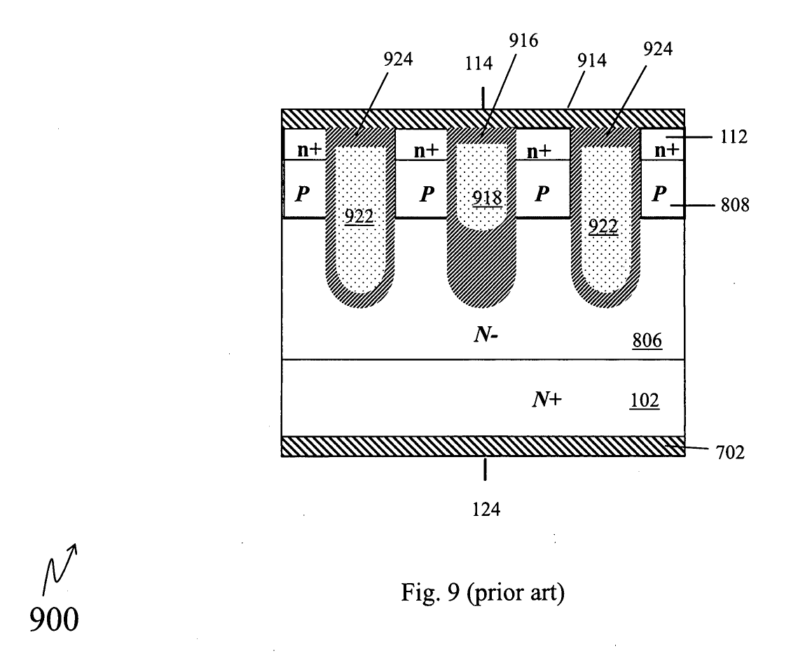

Other previously proposed structures, as shown in FIGS. 8 and 9 aim to achieve a lower Cgd either by gate shield electrode or a combination of thick bottom oxide and recessed field plate.

With reference to FIG. 8, a cross-sectional structural diagram depicts a conventional power MOSFET (800) having a split polysilicon gate configuration. A drain metallization region (124) adjoins a heavily doped drain region (102). The heavily doped drain region (102) adjoins a drain region (806). A body region (808) separates the drain region (806) from a source region (112). A source metallization region (114) connects to the source region (112). A trench region (318) adjoins the source region (112), the body region (808) and the drain region (806). The trench region (318) is typically an insulation material such as a dielectric. A gate electrode (116) is embedded within the insulation material in the trench region (318) such that the gate electrode (116) is capacitively connected to said body region (808). A second gate electrode (820) may be located between the gate electrode (116) and the drain region (806) and may be electrically connected to the source region (112).

With reference to FIG. 9, a cross-sectional structural diagram depicts a power MOSFET (900) including a recessed field plate (RFP) configuration. A drain metallization region (124) adjoins a heavily doped drain region (102). The heavily doped drain region (102) adjoins a drain region (806). A body region (808) separates the drain region (806) from a source region (112). A source metallization region (114) connects to the source region (112). A trench region (916) adjoins the source region (112), the body region (808) and the drain region (806). The trench region (916) is typically an insulation material such as a dielectric. A gate electrode (918) is embedded within the insulation material in the trench region (916) such that the gate electrode (918) is capacitively connected to said body region (908). A recessed field plate trench region (924) adjoins the source region (912), the body region (808) and drain region (806). The recessed field plate trench region (924) is typically an insulation material such as a dielectric. A recessed field plate (922) is positioned in the insulation material of the recessed field plate trench region (924). The recessed field plate (922) realizes a short channel region, less than 0.25 um, to furthermore reduce the gate-source capacitance and the gate-drain capacitance, leading to the total gate charge (Q_{g}) and the Miller charge (Q_{gd}) to be lowered accordingly.

As the requirements for more efficient power transistors increase, advantages are derived by MOSFET transistors with lowered Q_{gd}. One way to accomplish a lowered Q_{gd} is with narrow trench widths which provide smaller area of gate-drain overlap. Using advanced photolithographic and etching techniques trenches with narrow widths can be formed. However, there are two main difficulties to realize such narrow trench MOSFETs with the desired performance characteristics. The first difficulty is the ability to form a thick oxide layer (BOX) at the bottom of a trench. At present, BOX layer is created by either depositing oxide into trench and then etch back or by forming nitride spacer along the trench sidewall and growing the BOX by LOCOS process. For example, when trench width approaches 0.2 um or less, these two techniques will be very difficult to implement due to a minimum trench width required to form pad oxide and spacers for LOCOS oxidation. Similarly, it is difficult to avoid void generation if the dielectric (such as oxide) deposition method is used. The second difficulty is that polysilicon gate resistance (R_{g}) will increase significantly and the device switching performance will be degraded due to increased R_{g}*C_{g} value as the gate become very narrow and thin.

Trench devices, and related fabrication methods which include forming a first trench and forming a hardmask layer on sidewalls of the trench. A second trench may be etched narrower than the first trench, into the bottom of the first trench. A dielectric material may be grown to substantially fill the second trench, using a reaction process to which the hardmask material is substantially inert. The growing action also grows tapered portions of the dielectric material upwardly under part of the hardmask. A conductive layer may be formed over said dielectric material. The dielectric material in the second trench, in combination with the tapered portions which extend upward from the dielectric material may provide smooth gradation of voltage differences within the semiconductor material. The gradation may be caused by potential differences between the gate and various portions of the semiconductor material.

The disclosed innovations, in various embodiments, provide one or more of at least the following advantages. However, not all of these advantages result from every one of the innovations disclosed, and this list of advantages does not limit the various claimed inventions.

Avoiding possible strain maxima;

Uniform wall angle; and

Simple fabrication.

The numerous innovative teachings of the present application will be described with particular reference to a number of embodiments, including presently preferred embodiments (by way of example, and not of limitation), as well as other embodiments.

A power MOS transistor may include a thick bottom oxide having a high aspect ratio (t_{Box}/W) and a smooth transition region between trench wall oxide and the thick bottom oxide for improved performance and reliability. The described power MOSFET structures may provide improved conduction and reduce switching power losses.

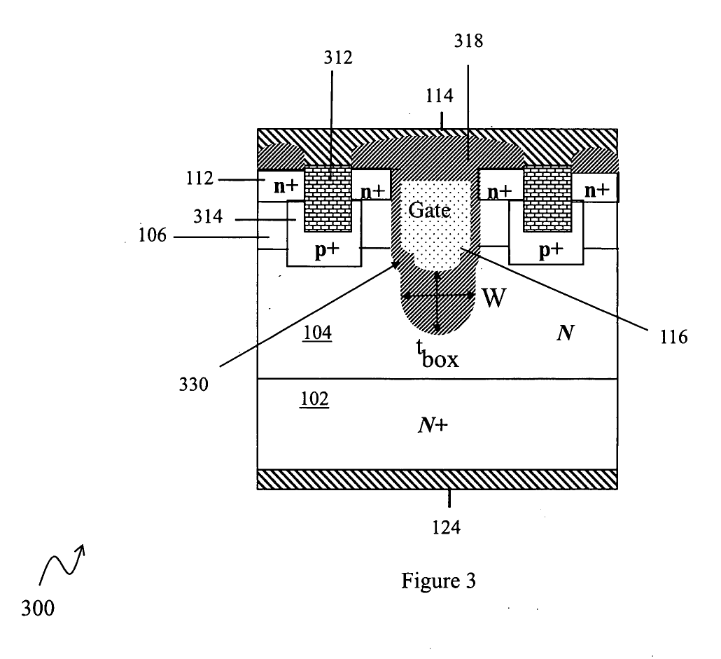

With reference to FIG. 3, a cross-sectional structural diagram depicts a power MOSFET 300, in accordance with a sample embodiment. Power MOSFET 300 may typically include an n-channel MOSFET basic cell structure including a drain metallization region 124 contacting a heavily-doped drain region 102. A drain region 104, adjoining the drain region 102, is separated from the source region 112 by a body region 106. Body contact region 314 adjoins the body region 106. A source and body metallization region 114 contacts the source region 112 and body contact region 314 through a trench contact 312. The trench insulation region 318 may be formed with a dielectric or other suitable insulation material. The trench insulation region 116 may be, for example, a silicon dioxide (oxide), a low temperature oxide (LTO), a phosphosilicate glass (PSG), a BPSG, or another insulative material. A gate electrode 116 is positioned within the trench insulation region 318.

The power MOSFET 300 may have a high aspect ratio of thick bottom oxide to trench width (t_{Box}/W) and a smooth transition 330 of oxide between trench wall oxide and bottom oxide. The gate oxide 318 thickness increases from the end of side wall channel region towards the thick bottom oxide. In this embodiment, the conducting material of the gate electrode 116 overlaps the Gate Oxide Transition Region (GOTR) 330. Furthermore, the p+ contact region 314 is deeper than the p-body region 106. The trench contact 312 maybe filled with conducting material such as tungsten or metal.

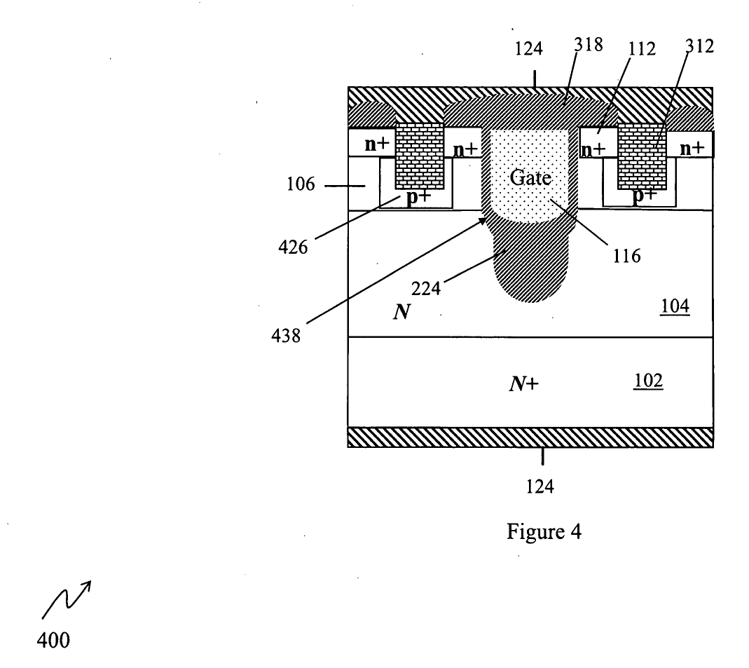

With reference to FIG. 4, a cross-sectional structural diagram depicts a power MOSFET 400, in accordance with an embodiment. The gate conducting material 116 partially overlaps a gate oxide transition region 438. The p⁺ contact region 426 lies above the p-body region 106.

The aspect ratio of thick bottom oxide to trench width (t_{Box}/W) may be greater than 0.7. In accordance with another embodiment, the aspect ratio of thick bottom oxide to trench width (t_{Box}/W) may be greater than 1.0.

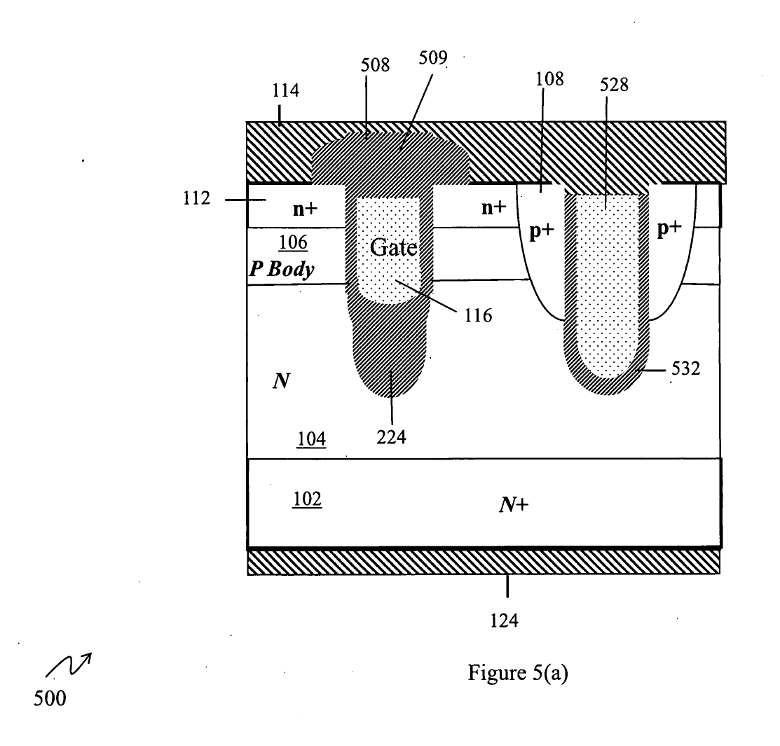

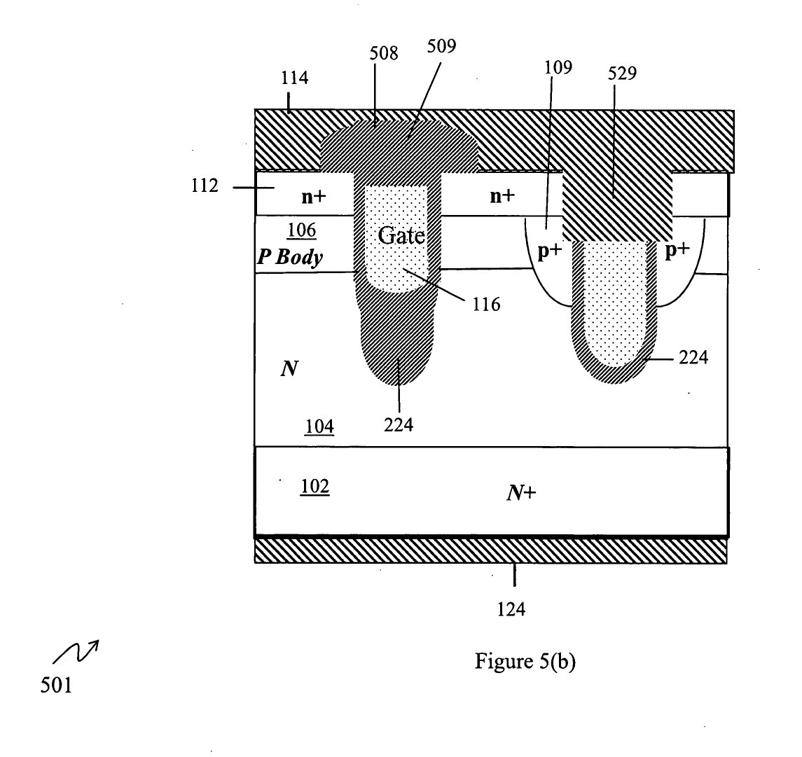

With reference to FIG. 5(a), a cross-sectional structural diagram depicts a power MOSFET 500, similar to the MOSFET of FIG. 9, in accordance with an embodiment. Power MOSFET 500 includes a recessed field plate (RFP) 528 embedded in an RFP oxide trench region 532. The gate trench insulation region 509 may be a dielectric or other suitable insulation material and is here shown having a lower gate insulation region 224 and an upper gate insulation region 508.

A high aspect ratio of thick bottom oxide to trench width (t_{Box}/W) with gate oxide thickness generally increasing from the side wall channel region towards the thick bottom oxide is implemented with an RFP 528. An RFP trench region 532 is filled with conducting material such as polysilicon and is connected to the source electrode.

The trench MOSFET 500 may include a gate trench region 509 filled with an n-type polysilicon material whereas the RFP trench region 532 may be filled with p-type polysilicon material.

The doping of the N-epitaxial drift region 104 may be non-uniformly doped. For example the doping can be graded to have higher doping at substrate and decreases towards the surface.

With reference to FIG. 5(b), a cross-sectional structural diagram depicts a power MOSFET 501, which is generally similar to the MOSFET of FIG. 5(a) except that the n+ source 112 extends to the recessed RFP contact region 529.

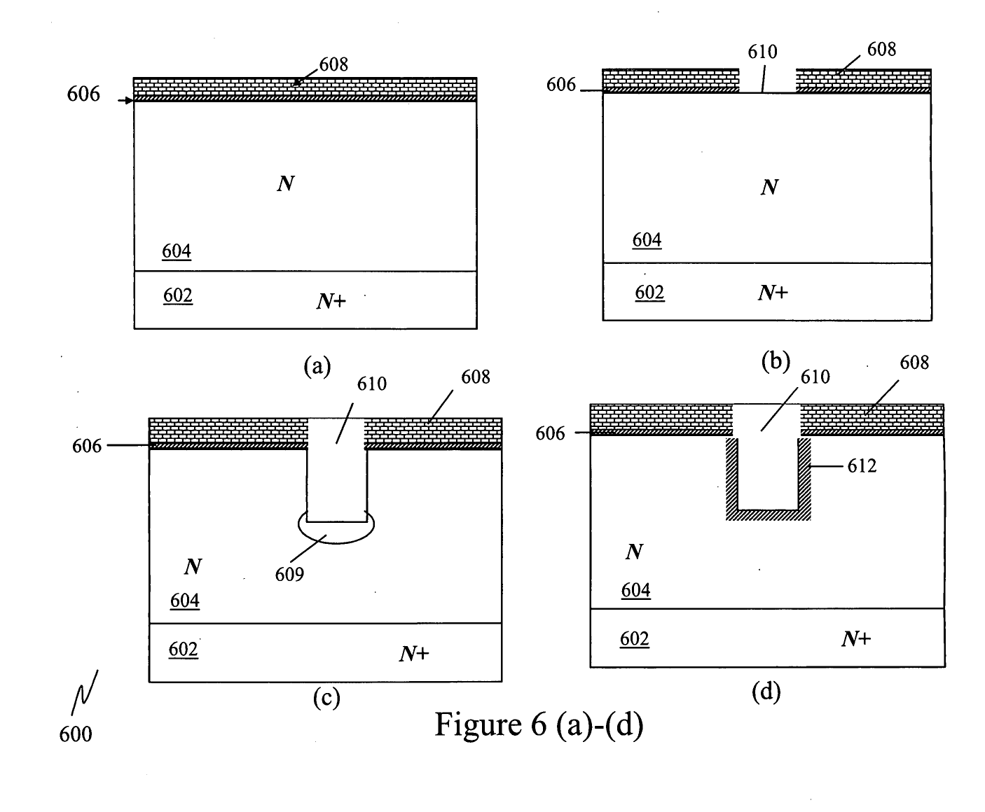

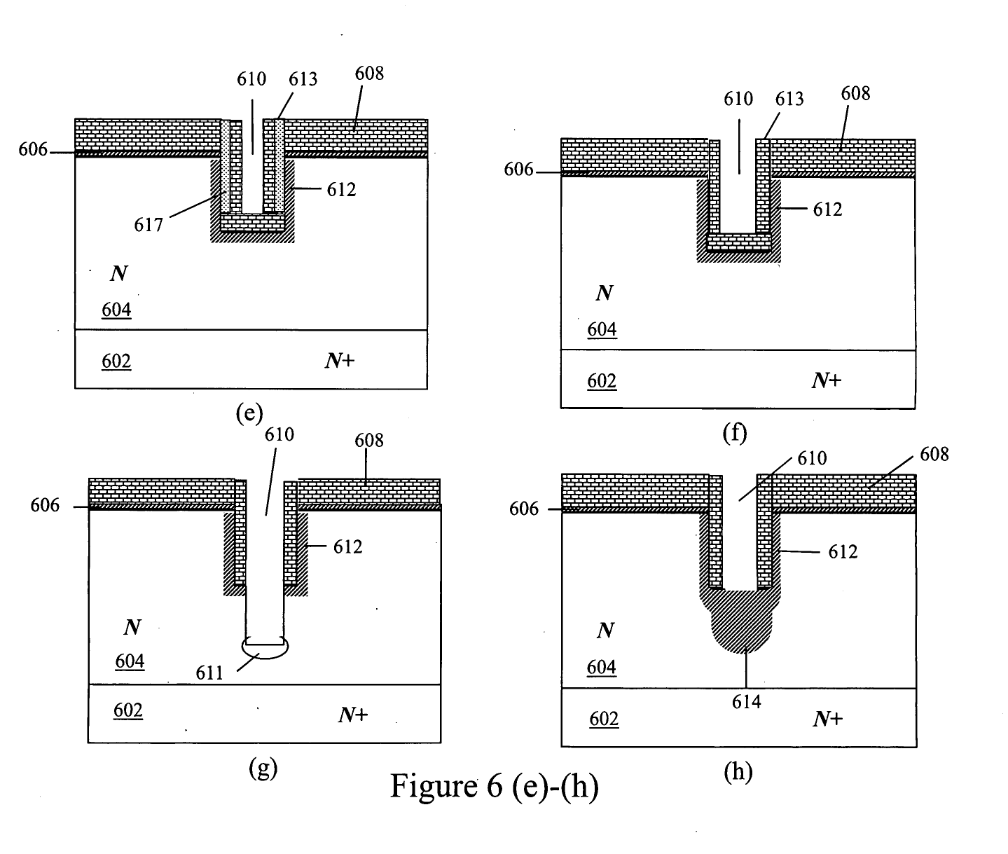

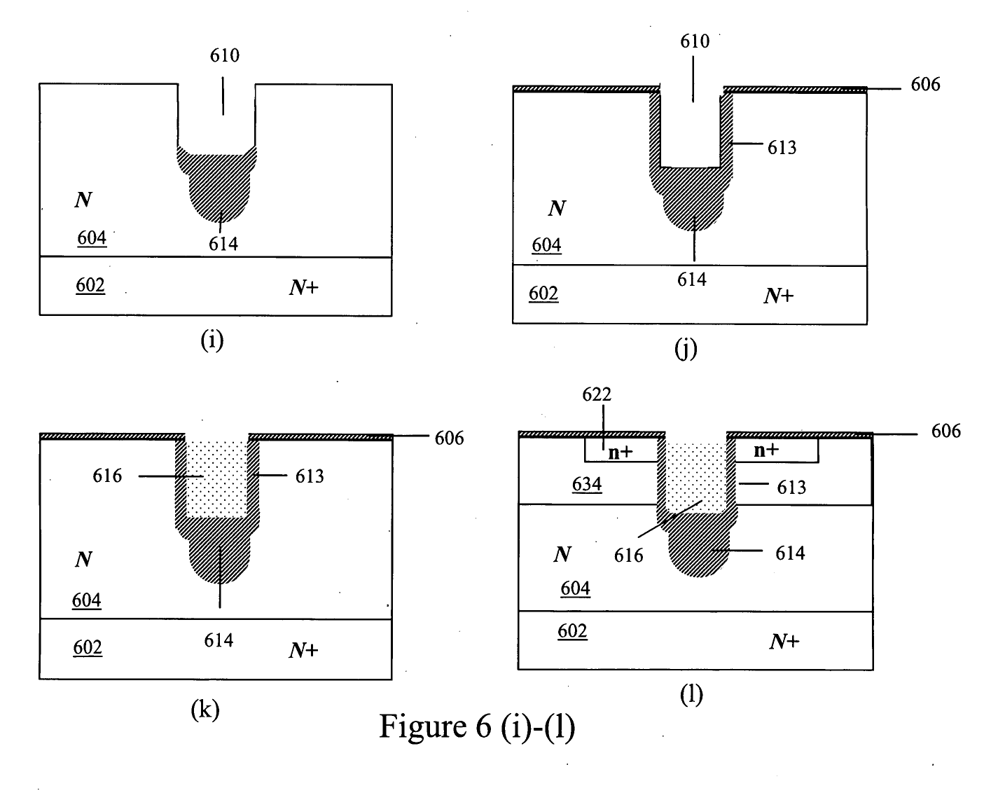

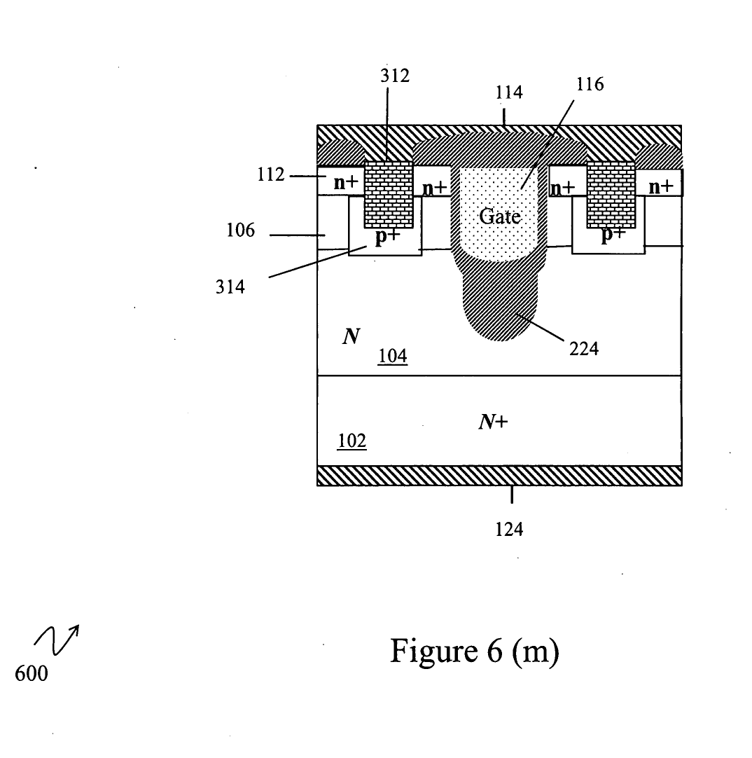

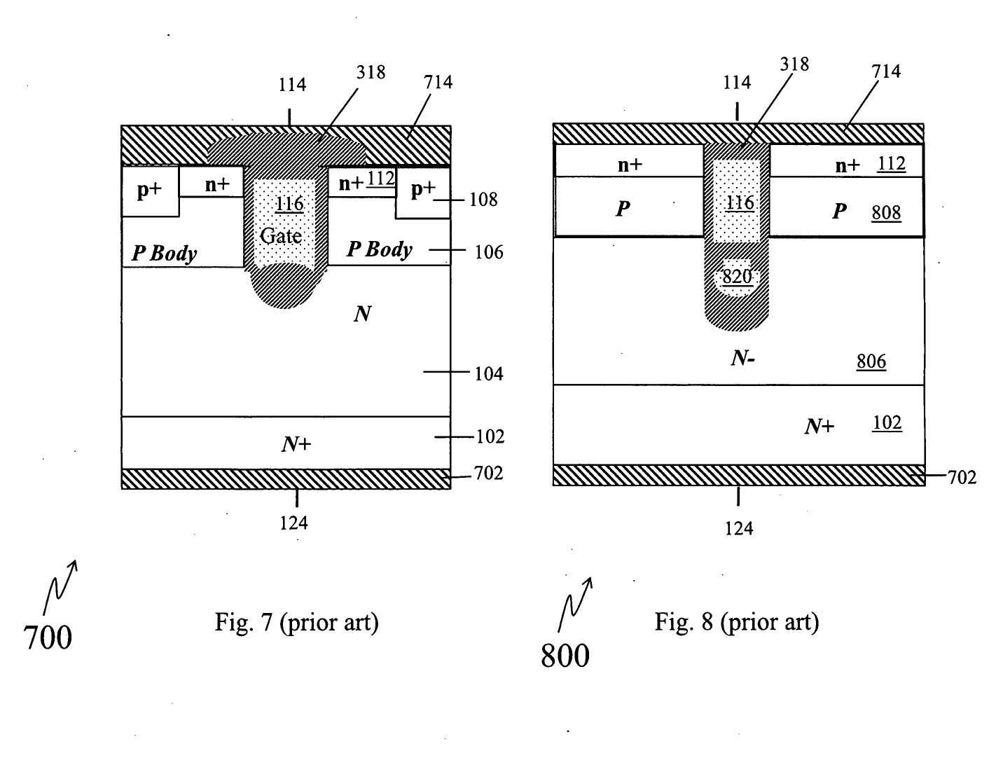

With reference to FIG. 6(a-m), cross-sectional structural diagrams depict stages of a method of making a power MOSFET, in accordance with an embodiment.

The process begins with a heavily doped N⁺ substrate 602 doped, for example, with Phosphorus or Arsenic. An n-type epitaxial layer 604 is grown on top of the N⁺ substrate 602. As shown in FIG. 6(a), a thin oxide layer 606 may be grown over the epitaxial layer 604 and a silicon nitride layer 608 may deposited on top of the oxide layer 606. The oxide layer 606 for example can be 200 A-500 A and the silicon nitride layer 608 can be, e.g., 1000 A-5000 A thick.

As shown in FIG. 6(b) a photoresist mask is used to etch the silicon nitride and oxide layers.

A trench 610 is then etched as shown in FIG. 6(c). A local doping enhancement implant 609, for example P³¹ or As, may be optionally introduced. A thin thermal oxide layer 612 is grown, e.g. 200 A to 1000 A, as shown in FIG. 6(d). An optional polysilicon layer 617 is then deposited for example of a thickness of 100 A-300 A, etched back then a nitride layer 613 is deposited for example of a thickness of 100 A-1000 A as shown in FIG. 6(e). Alternatively, after growing the thin oxide layer 612 as shown in FIG. 6(d) a nitride layer 613 is then deposited for example of a thickness of 100 A-1000 A as shown in FIG. 6(f).

The nitride 613 and oxide layer 612 at the bottom of the trench 610 are then etched using anisotropic dry etching and silicon is further etched as shown in FIG. 6(g). A local doping enhancement implant 611, for example P³¹ or As, may be introduced.

Thermal oxidation is used such that the lower portion 614 of the trench 610 is completely oxidized as shown in FIG. 6(h).

The nitride 608 and thin oxide 606 layers at the top of the wafer and trench 610 upper portion walls are etched as shown in FIG. 6(i)

Gate oxide 613 is grown and polysilicon 616 is deposited and etched back as shown in FIG. 6(j) and FIG. 6(k).

N+ Source 622 and P-body 634 regions are implanted and driven in using thermal or Rapid Thermal Anneal (RTA) techniques as shown in FIG. 6(l).

Oxide layer (such as LTO) deposition, contact and metal deposition and etching steps are then performed to yield the structure shown in FIG. 6(m).

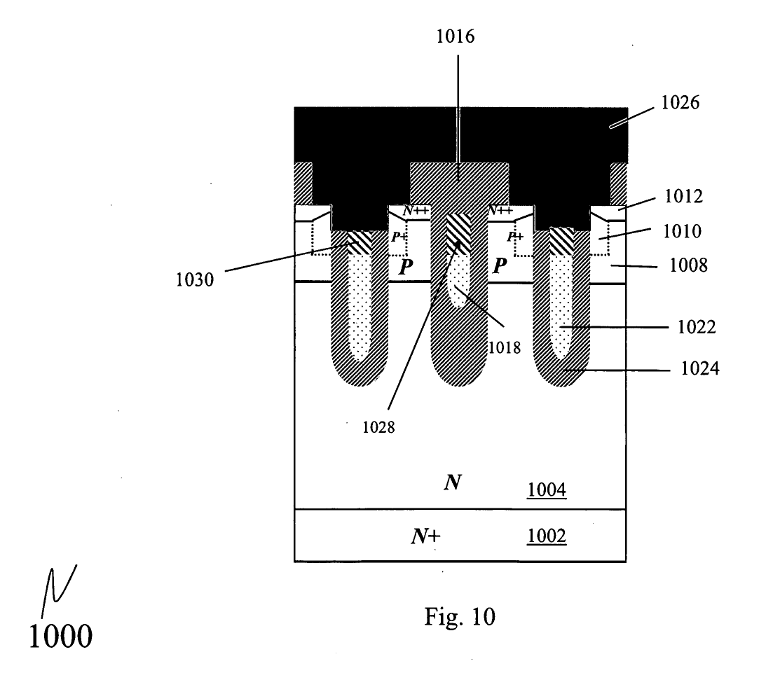

With reference to FIG. 10, a cross-sectional structural diagram depicts a power switch (1000) having a recessed field plate configuration, in accordance with an embodiment. A heavily doped drain region (1002) adjoins a lightly doped drain region (1004). A body region (1008) separates the lightly doped drain region (1004) from a source region (1012). A heavily doped body contact region (1010) may adjoin the body region (1008). A gate trench region (1016) may be filled by thermal oxidation with an insulation material such as a dielectric. A gate electrode (1018) may be embedded in the insulation material of the gate trench region (1016). A polycide portion (1028) of the gate electrode (1018) may be provided at the upper end of the gate electrode (1018) nearest the source region (1012). A recessed field plate trench region (1024) may adjoin the body region (1008) and the lightly doped drain region (1004). The recessed field plate trench region (1024) is filled with an insulation material such as a dielectric. A recessed field plate (1022) is embedded within the insulation material in the recessed field plate trench region (1024). A recessed field plate polycide portion (1030) may be provided at the upper portion of the recessed field plate (1022). A metal layer (1026) contacts the source region (1012), the body contact region (1010) and the recessed field plate polysilicon portion (1030).

The bottom thick oxide (BOX) in the gate trench region (1016) is formed by oxidizing the trench walls such that the oxide completely fills the whole gate trench region (1016) using thermal oxidation. Since a thermal oxidation process grows oxide from the interface between silicon and oxide along both sides of trench sidewalls as well as from the trench bottom, this technique of completely filling trench by thermal oxidation eliminates void generation. The problem of void creation often occurs in the oxide deposition process where the oxide layer is “grown” from the surface and not from the interface between the silicon and oxide. An additional advantage of using fully oxidized techniques is its relative insensitivity to oxidation parameters such as temperature and time.

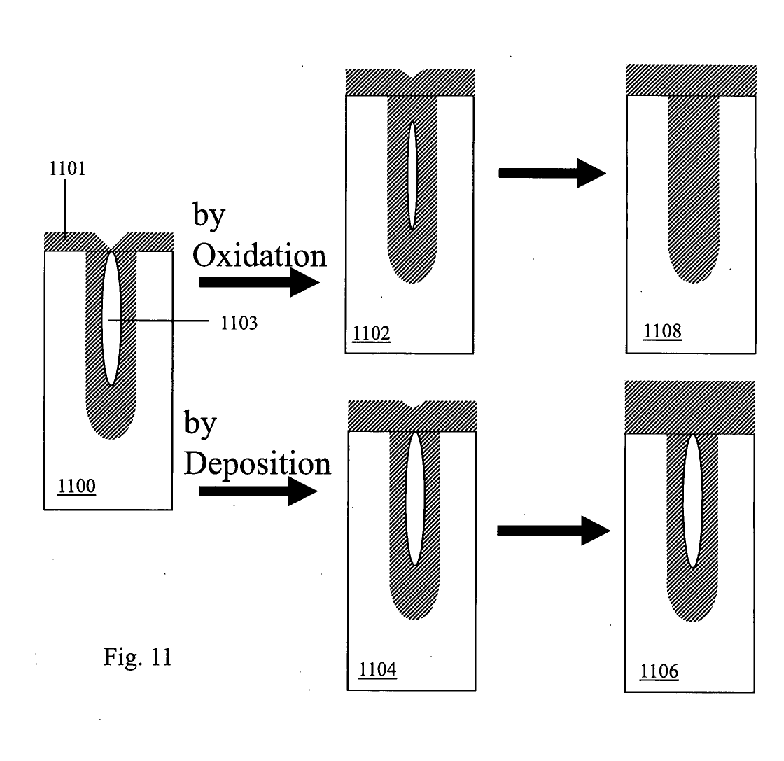

With reference to FIG. 11, a series of cross-sectional structural diagrams depict process stages. A first diagram (1100) depicts a trench (1103) and an initial oxide layer (1101). A second diagram (1102) depicts a first stage as further oxide is grown using thermal oxidation. A third diagram (1108) depicts a final stage after thermal oxidation having no voids within the oxide. A fourth diagram (1104) depicts a first stage as further oxide is formed using a deposition method. A fifth diagram (1106) depicts a final stage after deposition, having a void within the trench.

This set of alternative sequences shows how the use of growth (rather than deposition, in high-aspect-ratio trench fill, helps to avoid voids. The present inventors have realized that this difference not only allows reliable fill in a two-stage trench process (as described above), but can also be used to provide high-aspect ratio in single trenches.

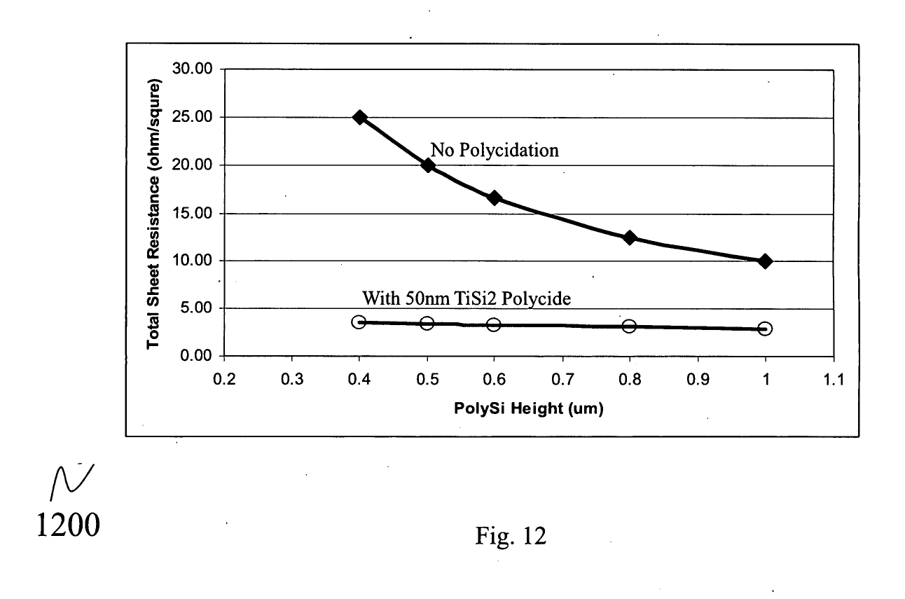

The polycide portion (1028) on the gate electrode (1018) shown in FIG. 10 provides, even with a very thin polysilicon gate, a reduced total sheet resistance of the gate polysilicon-polycide composite layer. This is shown by the analytical data graphed in FIG. 12. Therefore, the gate resistance R_{g} will be decreased even with a thin and very narrow polysilicon gate line which is required to have further reduction of the C_{gd} and Cᵢₛₛ.

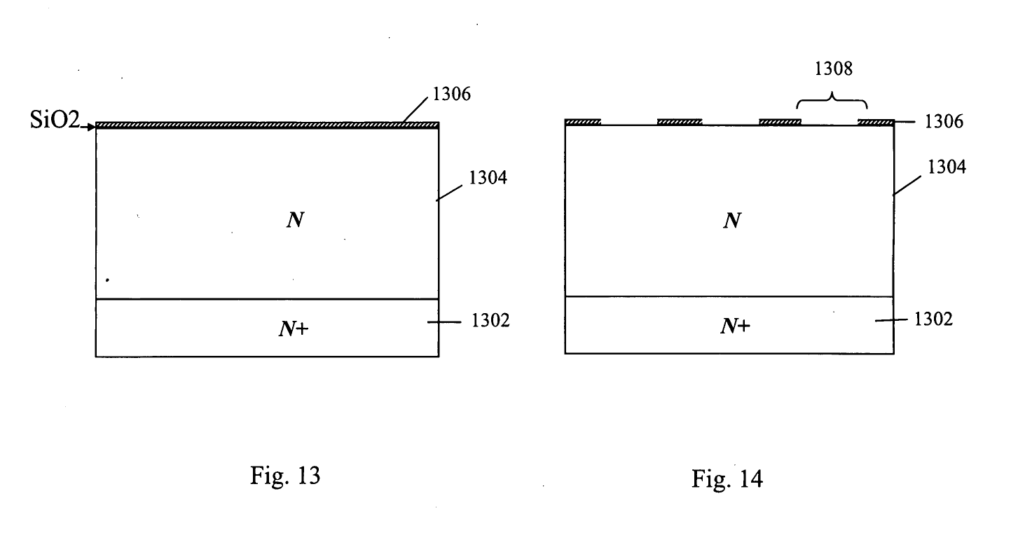

With reference to FIGS. 13-23, a series of cross-sectional structural diagrams depicts process stages for making a trench-gated MOSFET with RFP, in accordance with an embodiment.

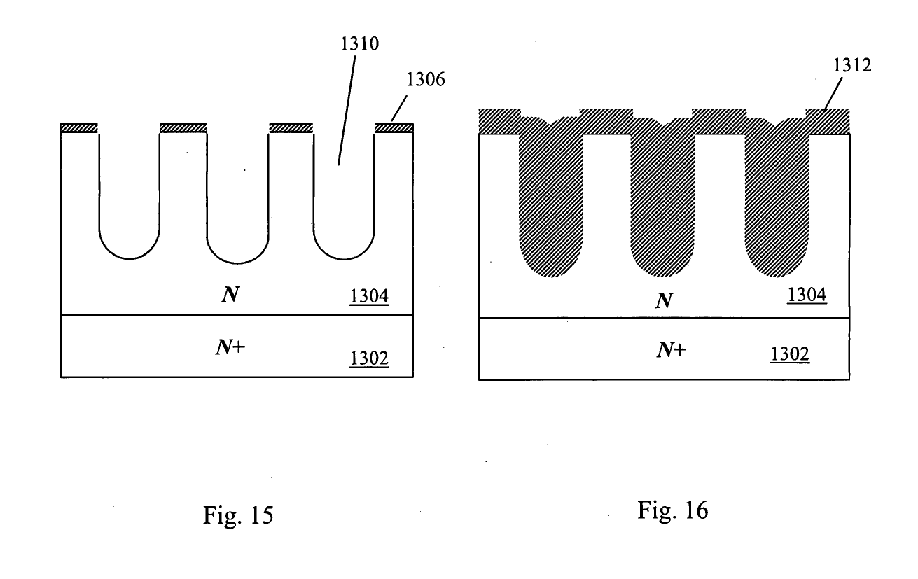

Starting with N+ substrate (1302), the N− epitaxial layer (1304) is grown followed by the oxidation (1306) as shown in FIG. 13. A trench mask may be used to form the hard mask (1306 and 1308) for a trench etch (FIG. 14). A silicon etch step is carried out to form the trench (1310) in FIG. 15, followed by a sacrificial oxidation (SacOX) to improve the trench sidewall roughness. The SacOX is then completely removed to expose a high quality bare silicon trench (1310).

A thermal oxidation step is then performed until the trench is completely filled up with the grown thermal oxide (1312), as shown in FIG. 16.

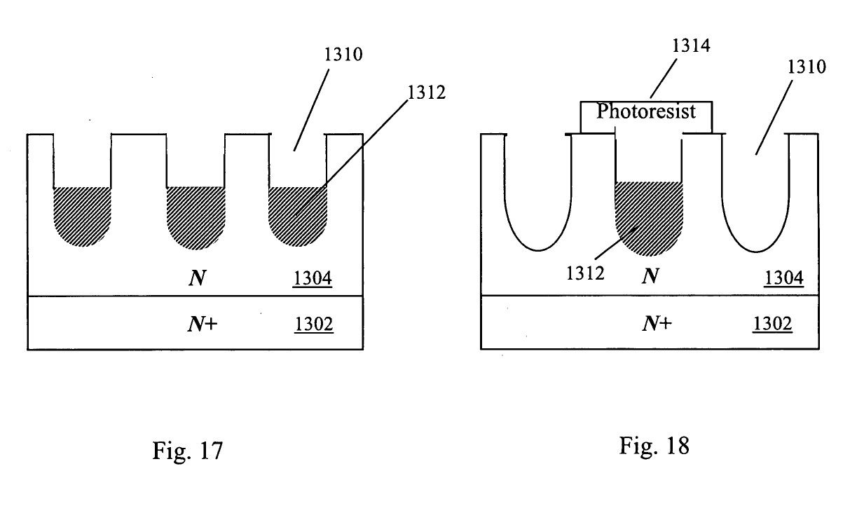

An oxide etch back process using dry, wet or combination of both is used to etch down the oxide in the trench (1310), forming the trench bottom oxide layer (1312) as shown in FIG. 17. The oxide in the non-active area of the device (not shown) can be protected during this etching back process by a photo mask. The un-etched oxide in the non-active region can be used as the “field oxide” commonly used in power semiconductor device.

Next, a BOX mask (1314) is used to protect the active gate trench and the edge termination. The oxide removal step follows to completely etch away the BOX (1312) inside the RFP trench (1310) as shown in FIG. 18.

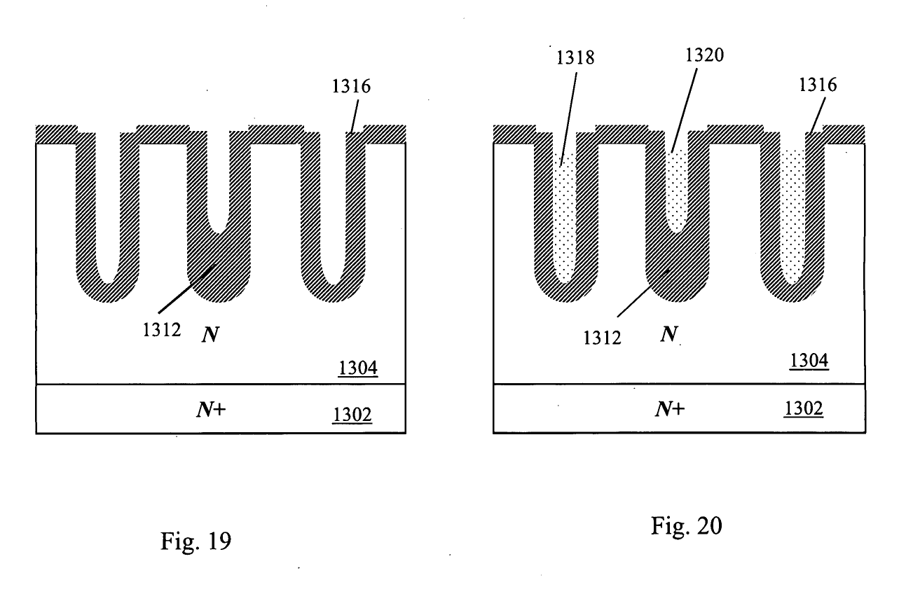

Gate oxide (1316) is then grown along the trench sidewall as shown in FIG. 19, followed by polysilicon deposition (1318 and 1320) and recess etch back which is illustrated in FIG. 20.

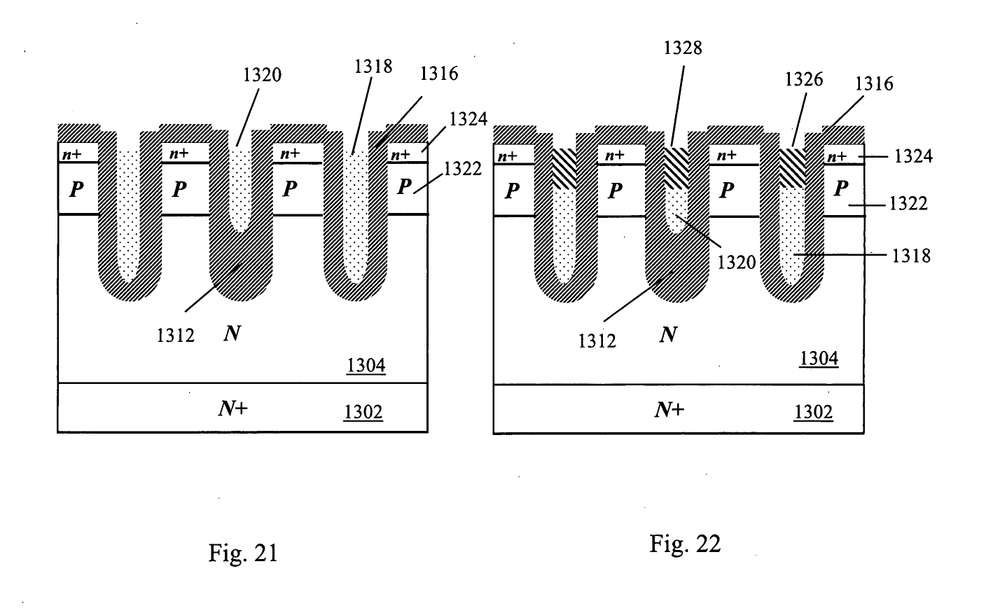

Body and source implants are performed to create the P body (1322) and n+ source (1324), as shown in FIG. 21. Subsequently, a careful clean step is applied to remove the oxide residual and organic residuals in the polysilicon surfaces (1320 and 1318).

A thin Ti layer is deposited and the sintering process is performed to form the polycide (TiSi₂) layers (1328 and 1326). Then, the un-reacted Ti layer is stripped away completely. This is demonstrated in FIG. 22, where the TiN barrier layer can be additionally deposited on TiSi₂ surface for preventing from possible negative impact from Inter-Level-Dielectric (ILD) layer in the following process. A source and body metallization layer (1332) may contact the source region (1324) and the body contact region (1330).

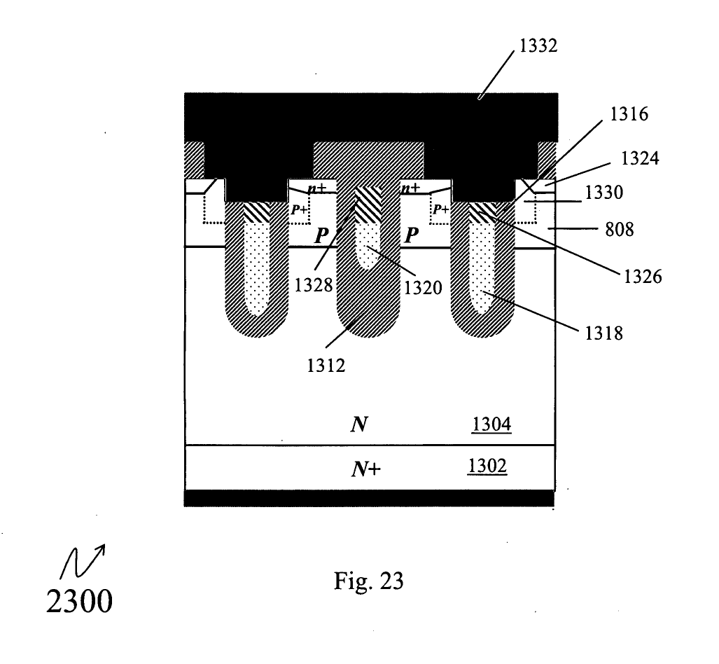

The rest of process steps are similar to one of a standard trench-gated MOSFET, so that the final device structure (2300) is shown in FIG. 23. It is important to point out the maximum temperature of all the thermal process after polycide may be controlled to be less than the stable temperature of the polycide. For example, the stable temperature of TiSi₂ layer should be less than 900° C., and the stable temperature of TaSi₂ must be less than 1000° C.

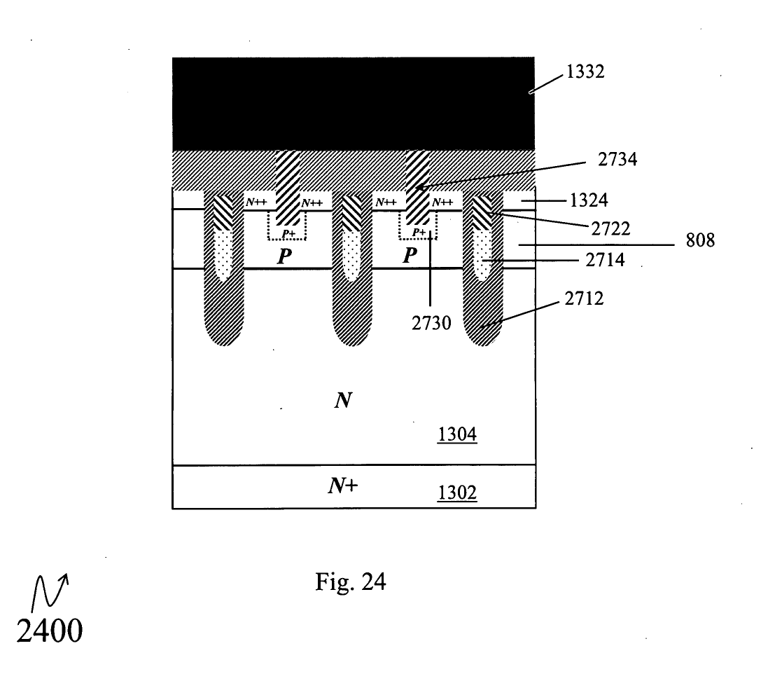

FIG. 24 shows an alternative embodiment wherein a deep body contact 2730 is used. In this figure all trenches are shown as identical, but of course the deep body contact structure of this figure can be combined with the RFP trenches of e.g. FIG. 23.

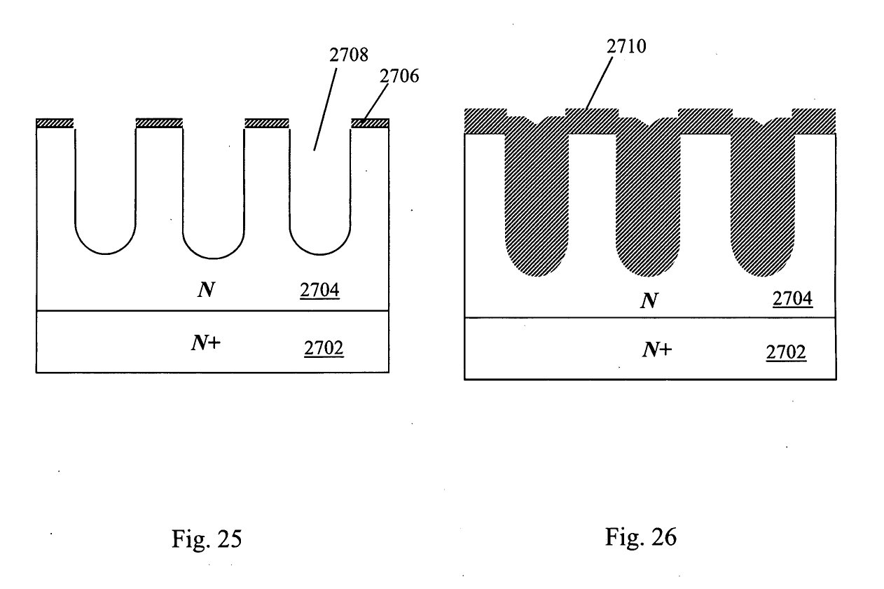

With reference to FIGS. 25-32, a series of cross-sectional structural diagrams depicts process stages, in accordance with an embodiment. Starting with N+ substrate (2702), the N− epitaxial layer (2704) is grown followed by the oxidation (2706) as shown in FIG. 25. A silicon etch step is carried out to form the trench (2708) in FIG. 25, followed by a sacrificial oxidation (SacOX) to improve the trench sidewall roughness.

The SacOX is then completely removed to expose a high quality bare silicon trench (2708). A thermal oxidation step is then performed until the trench is completely filled up with the grown thermal oxide (2710), as shown in FIG. 26.

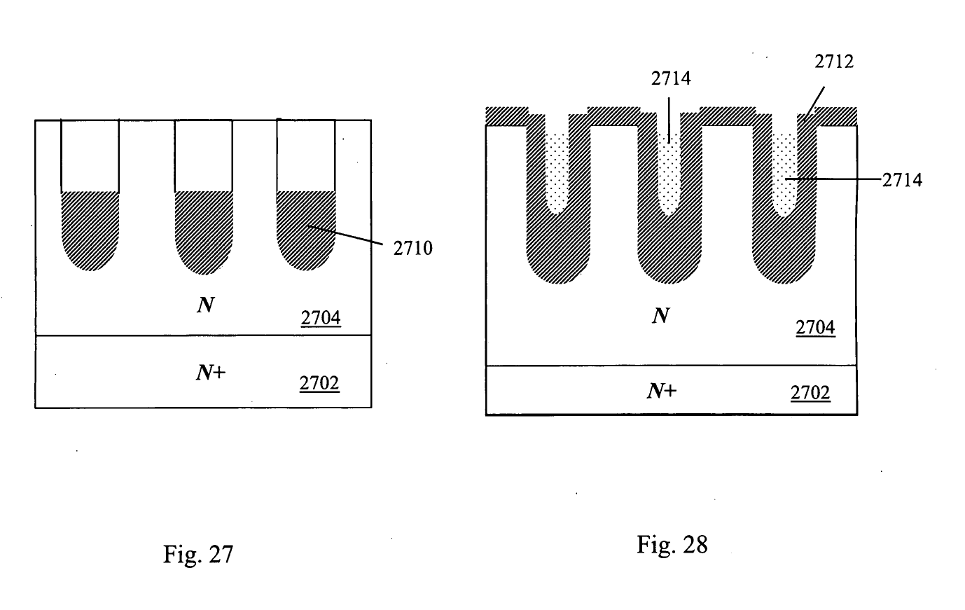

An oxide etch back process using dry, wet or combination of both is used to etch down the oxide in the trench (2708), forming the trench bottom oxide layer (2710) as shown in FIG. 27. Gate oxide (2712) is then grown along the trench sidewall as shown in FIG. 28, followed by polysilicon deposition (2714) and recess etch back.

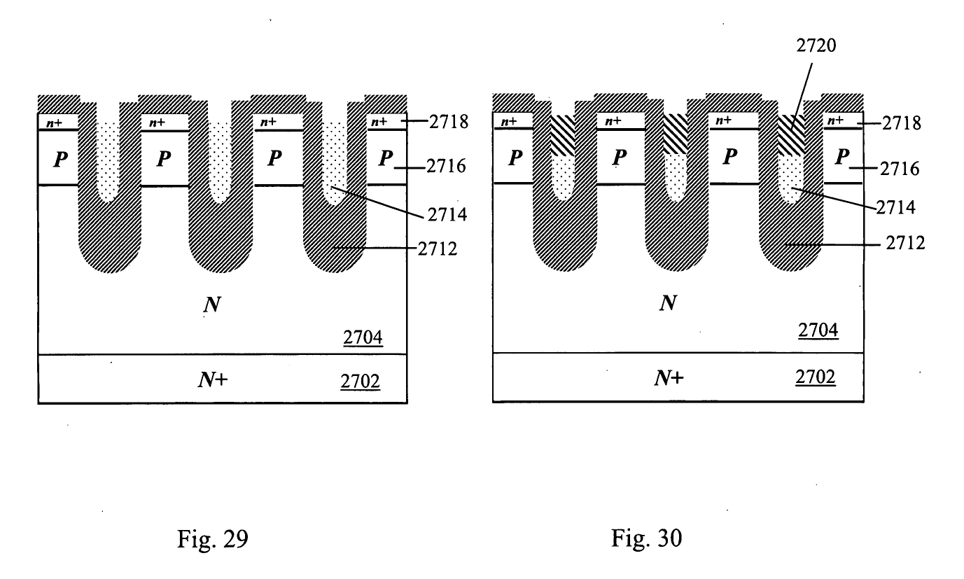

Body and source implants are performed to create the P body (2716) and n+ source (2718), as shown in FIG. 29.

Subsequently, a careful clean step is applied to remove the oxide residual and organic residuals in the polysilicon surfaces (2714). A thin Ti layer is deposited and the sintering process is performed to form a polycide (TiSi₂) layer (2720). Then, the unreacted Ti layer is stripped away completely. This is demonstrated in FIG. 30, where the TiN barrier layer can be additionally deposited on TiSi₂ surface for preventing from possible negative impact from Inter-Level-Dielectric layers.

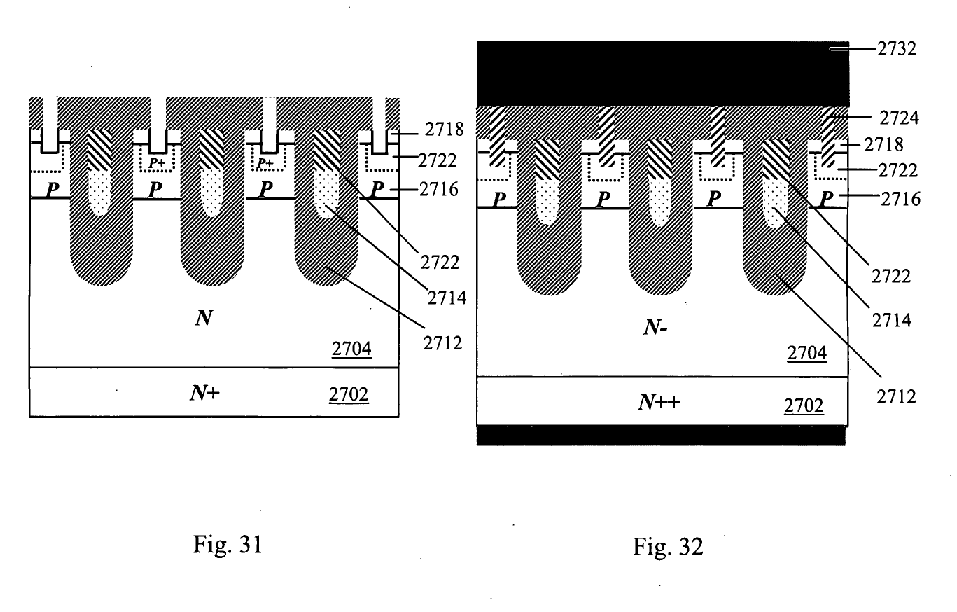

Contact trenches are then etched as shown in FIG. 31. A tungsten plug (2724) may be implanted to connect to the source region (2718).

A source and body metallization layer (2732) may contact the source region (2724). The rest of process steps are similar to one of a standard trench-gated MOSFET, so that the final device structure is shown in FIG. 32. It is important to point out the maximum temperature of all the thermal process after polycide may be controlled to be less than the stable temperature of the polycide. For example, the stable temperature of TiSi₂ layer should be less than 900° C., and the stable temperature of TaSi₂ must be less than 1000° C. A tungsten plug (2724) with Ti/TiN as the barrier metal is used in the n+ source (2718) contact area for the purpose of achieving good metal step coverage.

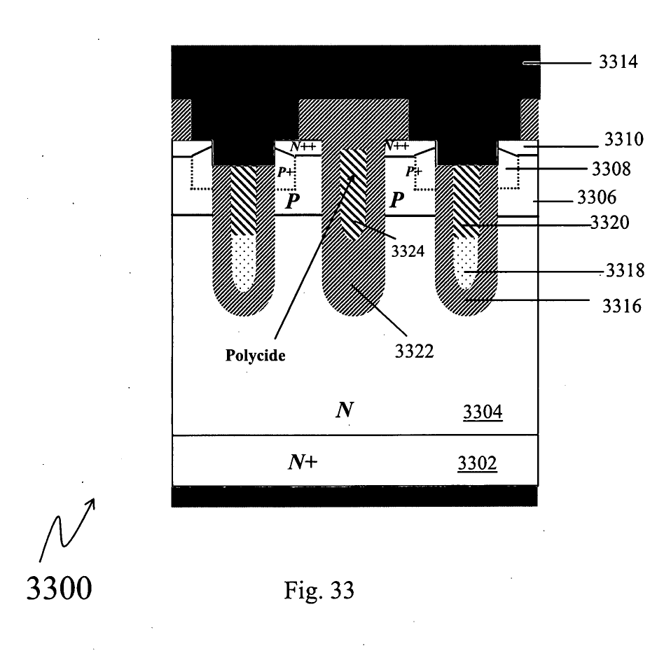

With reference to FIG. 33, a cross-sectional structural diagram depicts a power switch (3300) having a recessed field plate configuration, in accordance with an embodiment. A heavily doped drain region (3302) adjoins a lightly doped drain region (3304). A body region (3306) separates the lightly doped drain region (3304) from a source region (3310). A heavily doped body contact region (3308) may adjoin the body region (3306). A gate trench region (3322) may be filled by thermal oxidation with an insulation material such as a dielectric. A gate electrode (3324) may be embedded in the insulation material of the gate trench region (3322). A recessed field plate trench region (3316) may adjoin the body region (3306) and the lightly doped drain region (3304). The recessed field plate trench region (3316) is filled with an insulation material such as a dielectric. A recessed field plate (3318) is embedded within the insulation material in the recessed field plate trench region (3316). A recessed field plate polysilicon portion (3320) may be provided at the upper portion of the recessed field plate (3318). A metallization layer (3314) contacts the source region (3310), the body contact region (3308) and the recessed field plate polysilicon portion (3320).

When the gate polysilicon becomes very thin the gate polysilicon area can be completely silicided, as shown in FIG. 33.

According to various disclosed embodiments, there is provided a method of fabricating a power semiconductor device, which may include forming a first trench in a semiconductor material and forming a hardmask layer on sidewalls of the first trench. A second trench may be etched into the bottom of the first trench. A dielectric material may be grown to substantially fill the second trench. A conductive layer may be formed over the dielectric material. The dielectric material in the second trench, in combination with the tapered portions extending upward from the dielectric material may provide a smooth gradation of voltage differences within the semiconductor material.

According to various disclosed embodiments, there is provided a method of fabricating a trench device includes forming a first trench and forming a hardmask layer on sidewalls of the trench. A second trench may be etched narrower than the first trench, into the bottom of the first trench. A dielectric material may be grown to substantially fill the second trench, using a reaction process to which the hardmask material is substantially inert. The growing action also grows tapered portions of the dielectric material upwardly under part of the hardmask. A conductive layer may be formed over said dielectric material. The dielectric material in the second trench, in combination with the tapered portions which extend upward from the dielectric material may provide smooth gradation of voltage differences within the semiconductor material. The gradation may be caused by potential differences between the gate and various portions of the semiconductor material.

According to various disclosed embodiments, there is provided a power MOSFET which may include a trench having at least an upper and a lower part. The lower part of the trench may be filled with an insulating material. Tapered extensions in the lower part of the trench may extend upwardly from the insulating material. A conductive electrode may be positioned in the upper part of the trench.

According to various disclosed embodiments, there is provided a power device which may include a source electrode adjoining a trench. The trench may have at least an upper and a lower part. The lower part may be filled with an insulating material. Tapered extensions in the lower part of the trench may extend upwardly from the insulating material. A gate electrode may be positioned in the upper part of the trench.

According to various disclosed embodiments, there is provided a method of fabricating a power device may include forming a first trench and etching a second trench narrower than the first trench into the bottom of the first trench. A dielectric material may be grown to substantially fill the second trench, wherein the growing action also grows tapered portions of the dielectric material upwardly. A conductive layer may be placed over the dielectric material.

According to various disclosed embodiments, there is provided a method of fabricating a power semiconductor device which may include forming a first trench in a semiconductor material and forming a hardmask layer on sidewalls of the first trench. A second trench may be etched into the bottom of the first trench. A dielectric material may be grown to substantially fill the second trench. A conductive layer may be formed over the dielectric material. The dielectric material in the second trench, in combination with the tapered portions extending upward from the dielectric material may provide a smooth gradation of voltage differences within the semiconductor material.

### MODIFICATIONS AND VARIATIONS

As will be recognized by those skilled in the art, the innovative concepts described in the present application can be modified and varied over a tremendous range of applications, and accordingly the scope of patented subject matter is not limited by any of the specific exemplary teachings given. It is intended to embrace all such alternatives, modifications and variations that fall within the spirit and broad scope of the appended claims.

Numerous variations of the MOSFETs described above are within the scope of this invention. For example, a stepped oxide may line the gate trench and/or the RFP trench.

For another example, quasi-vertical designs could be implemented as well as vertical MOSFETs.

The conductivity of the various parts of the described MOSFETs can be changed to implement further embodiments. In particular, the design may be equally applicable to p-channel MOSFETs where the polarities of the layers are reversed.

All of the above variants of the structure may be realized in stripe or a cellular layout, such as square, rectangular, hexagonal or circular layouts.

A variety of oxidizable semiconductors can alternatively be used, e.g. Si_{.9}Ge_{.1}. At low Ge percentage, e.g. 20% or less, the grown oxide is stable. Insulator layers may be, for example, a low temperature oxide (LTO), a phosphosilicate glass (PSG), a borophosphosilicate glass (BPSG), or another insulative material.

It is worth noting that an alternative optional process is to use a nitride layer that covers the silicon surface before etching the trench. This will minimize oxide growth at the surface during trench oxidation

Although described generically as a MOSFET, it would be apparent to those having skill in the art that the designs could implement a variety of gated vertical high-voltage devices. Metal-insulator-semiconductor devices, such as the MOSFET, may include Insulated Gate Bipolar Transistors (IGBT), MOS gated thyristors and other suitable devices.

The following applications may contain additional information and alternative modifications: Attorney Docket No. MXP-14P, Ser. No. 61/125,892 filed Apr. 29, 2008; Attorney Docket No. MXP-15P, Ser. No. 61/058,069 filed Jun. 2, 2008 and entitled “Edge Termination for Devices Containing Permanent Charge”; Attorney Docket No. MXP-16P, Ser. No. 61/060,488 filed Jun. 11, 2008 and entitled “MOSFET Switch”; Attorney Docket No. MXP-21P, Ser. No. 61/084,642 filed Jul. 30, 2008 and entitled “Silicon on Insulator Devices Containing Permanent Charge”; Attorney Docket No. MXP-18P, Ser. No. 61/076,767 filed Jun. 30, 2008 and entitled “Trench-Gate Power Device”; Attorney Docket No. MXP-19P, Ser. No. 61/080,702 filed Jul. 15, 2008 and entitled “A MOSFET Switch”; Attorney Docket No. MXP-20P, Ser. No. 61/084,639 filed Jul. 30, 2008 and entitled “Lateral Devices Containing Permanent Charge”; Attorney Docket No. MXP-13P, Ser. No. 61/065,759 filed Feb. 14, 2009 and entitled “Highly Reliable Power MOSFET with Recessed Field Plate and Local Doping Enhanced Zone”; Attorney Docket No. MXP-22P, Ser. No. 61/027,699 filed Feb. 11, 2008 and entitled “Use of Permanent Charge in Trench Sidewalls to Fabricate Un-Gated Current Sources, Gate Current Sources, and Schottky Diodes”; Attorney Docket No. MXP-23P, Ser. No. 61/028,790 filed Feb. 14, 2008 and entitled “Trench MOSFET Structure and Fabrication Technique that Uses Implantation Through the Trench Sidewall to Form the Active Body Region and the Source Region”; Attorney Docket No. MXP-24P, Ser. No. 61/028,783 filed Feb. 14, 2008 and entitled “Techniques for Introducing and Adjusting the Dopant Distribution in a Trench MOSFET to Obtain Improved Device Characteristics”; Attorney Docket No. MXP-25P, Ser. No. 61/091,442 filed Aug. 25, 2008 and entitled “Devices Containing Permanent Charge”; Attorney Docket No. MXP-27P, Ser. No. 61/118,664 filed Dec. 1, 2008 and entitled “An Improved Power MOSFET and Its Edge Termination”; and Attorney Docket No. MXP-28P, Ser. No. 61/122,794 filed Dec. 16, 2008 and entitled “A Power MOSFET Transistor”.

None of the description in the present application should be read as implying that any particular element, step, or function is an essential element which must be included in the claim scope: THE SCOPE OF PATENTED SUBJECT MATTER IS DEFINED ONLY BY THE ALLOWED CLAIMS. Moreover, none of these claims are intended to invoke paragraph six of 35 USC section 112 unless the exact words “means for” are followed by a participle.

The claims as filed are intended to be as comprehensive as possible, and NO subject matter is intentionally relinquished, dedicated, or abandoned.

1. A method of fabricating a trench device, comprising:
forming a first trench, forming a hardmask layer on sidewalls of said trench, and etching a second trench, which is narrower than said first trench, into the bottom of said first trench;
growing a dielectric material to substantially fill said second trench, using a reaction process to which said hardmask material is substantially inert; and
forming a conductive layer over said dielectric material;
whereby said dielectric material in said second trench provides smooth gradation of voltage differences, within said semiconductor material, which may be caused by potential differences between said gate and various portions of said semiconductor material.

2. The method of claim 1, wherein said hardmask is silicon nitride material.

3. The method of claim 1, wherein said hardmask is a combination of polysilicon and silicon nitride layers.

4. The method of claim 1, further comprising removing said hardmask layer from the bottom of said trench but not from said sidewalls of said trench.

5. The method of claim 1, further comprising removing said hardmask and forming an insulating layer on said sidewalls.

6. The method of claim 1, wherein said trench device is a trench MOSFET.

7. A power MOSFET comprising;
a trench having at least an upper and a lower part, said lower part being filled with an insulating material;
tapered insulating extensions in said lower part of said trench, extending upwardly from said insulating material; and
a conductive electrode in said upper part of said trench.

8. The power MOSFET of claim 7, further comprising insulating material on a sidewall of said upper part.

9. The power MOSFET of claim 7, having an aspect ratio of thick bottom oxide to trench width greater than 0.7.

10. The power MOSFET of claim 7, having an aspect ratio of thick bottom oxide to trench width greater than 1.0.

11. The power MOSFET of claim 7, wherein said conductive electrode is a gate electrode.

12. The power MOSFET of claim 7, further comprising a trench contact.

13. The power MOSFET of claim 7, further comprising a recessed field plate.

14. A power device comprising:
a source electrode;
a trench adjoining said source electrode, said trench having at least an upper and a lower part, said lower part being filled with an insulating material; and
tapered extensions in said lower part of said trench, extending upwardly from said insulating material; and
a gate electrode in said upper part of said trench.

15. The power device of claim 14, further comprising insulating material on a sidewall of said upper part.

16. The power device of claim 14, having an aspect ratio of thick bottom oxide to trench width greater than 0.7.

17. The power device of claim 14, having an aspect ratio of thick bottom oxide to trench width greater than 1.0.

18. The power device of claim 14, further comprising a trench contact.

19. The power device of claim 14, further comprising a recessed field plate.

20. The power device of claim 14, further comprising a drain electrode.

21-77. (canceled)
